(19) United States
(12) Patent Application Publication
(10) Pub. No.: US 2002/0154455 A1
(43) Pub. Date: Oct. 24, 2002

(54) Magnetic device with a coupling layer and method of manufacturing and operation of such device

(76) Inventor: Kars-Michiel Hubert Lenssen, Eindhoven (NL)

Correspondence Address: Corporate Patent Counsel, U.S. Philips Corporation, 580 White Plains Road, Tarrytown, NY, 10591, US

(21) Appl. No.: 09/801,630

(22) Filed: Mar. 8, 2001

(30) Foreign Application Priority Data
Mar. 9, 2000 (EP) 00200829.0

(51) Int. Cl. G11B 5/39; G11C 11/15

(52) U.S. Cl. 360/324; 365/158

(57) ABSTRACT

In a magnetic data storage system or a magnetic sensing system including a GMR-structure, a set of structures is introduced that influences an intrinsic magnetic or magneto resistance characteristic such as the field-offset of the GMR-structure. The set of structures is separated from the GMR-structure by a high-resistive metallic material such as Ta.

The present invention is related to the field of magnetic devices. More in particular, a magnetic data storage system and a sensing system of magnetic characteristics, the systems having a coupling layer, are disclosed. A method of manufacturing such systems is also disclosed.

Magnetic devices are known in the art. Spin-valve structures such as Giant Magneto Resistance (GMR) and Spin-tunnel Magneto Resistance (TMR) devices recently have been extensively studied and were subject of a vast number of disclosures. GMR- and TMR-devices comprise as a basic building stack two ferromagnetic layers separated by a separation layer of a non-magnetic material. This structure in the sequel is referred to as the basic GMR- or TMR-stack of the magnetic device, or is referred to as the GMR- or TMR-structure. Such structure has a magneto resistance characteristic and shows the GMR- or TMR-effect. The separation layer is a non-ferromagnetic metallic layer for GMR-devices, and is a non-metallic, preferably insulating, layer for TMR-devices. Over the separation layer, there is a magnetic coupling between the two ferromagnetic layers. The insulating layer in the TMR-devices allows for a significant probability for quantum mechanical tunneling of electrons between the two ferromagnetic layers. Of the two ferromagnetic layers, one is a so-called free layer, and one is a so-called or hard pinned layer. The free layer is a layer whose magnetization direction can be changed by applied magnetic fields with a strength lower, preferably substantially lower, than the strength of the field required for changing the magnetization direction of the pinned layer. Thus the pinned layer has a preferred, rather fixed magnetization direction, whereas the magnetization direction of the free layer can be changed quite easily under an external applied field. A change of the magnetization of the free layer changes the resistance of the TMR- or GMR-device. This results in the so-called magneto resistance effect of these devices. The characteristics of these magnetic devices or systems can be exploited in different ways. For example a spin valve read-out element utilizing the GMR-effect can be used for advanced hard disk thin film heads. Also magnetic memory devices such as stand-alone or non-volatile embedded memory devices can be made based on the GMR- or TMR-elements. An example of such memory devices are MRAM devices. A further application is a sensor device or system for magnetic characteristics. Such sensors are used for example in anti-lock braking (ABS) systems or other automotive applications.

It is often required in a number of applications to modify, change or influence at least one intrinsic magnetic characteristic of the GMR- or TMR-devices. For example the magneto resistance output curve of the devices exhibits a field offset as a result of the magnetic coupling between the ferromagnetic layers. For most applications, this intrinsic magnetic characteristic causes a problem since the required operation ranges usually need to be at or around zero external field. This offset characteristic can be balanced by external biasing magnets but such measure is often not desired because of the higher cost and design limitations of the devices.

U.S. Pat. No. 6,023,395 discloses a magnetic tunnel junction magnetoresistive sensor for sensing magnetic fields when connected to sense cicuitry that detects changes in electrical resistance within the sensor. The magnetic tunnel junction has a stack of layers comprising a first structure of layers and a second structure of layers separated by a spacer layer.

The first structure of layers comprises a first ferromagnetic layer having its magnetic moment fixed in a preferred direction in the absence of an applied magnetic field, as a separation layer an insulating tunnel barrier layer in contact with the fixed ferromagnetic layer and a second ferromagnetic sensing layer in contact with the insulating tunnel barrier layer. The second structure of layers comprises a biasing ferromagnetic layer for biasing the magnetic moment of the sensing ferromagnetic layer in a preferred direction in the absence of an applied magnetic field. The spacer layer separates the biasing ferromagnetic layer from contact with the second ferromagnetic sensing layer and the first fixed ferromagnetic layer and comprises an electrically conductive nonferromagnetic material. The sense current flows perpendicular through the layers in the magnetic tunnel junction stack. In order to stabilize and linearize the output of the sensor, the demagnetizing field from the biasing ferromagnetic layer magnetostatically couples with the edges of the second ferromagnetic sensing layer. A disadvantage of the known sensor is that the antiferromagnetic magnetostatic coupling at the edges of magnetic layers depends on the geometry of the device, particularly the relevant layers thereof. Therefore, it is a difficult to obtain a homogeneous bias field strength over the magnetic tunnel junction area. In order to prevent direct ferromagnetic coupling between the biasing ferromagnetic layer and the second ferromagnetic sensing layer, the spacer layer must be relatively thick, but on the other hand must be still thin enough to permit antiferromagnetic magnetostatic coupling with the second ferromagnetic sensing layer. The disclosed measure is only related to magnetic tunnel junction magnetoresistive sensors. The relatively thick spacer layer introduces undesired electrical shunting in case of a current-in-plane configuration. This effect makes an antiferromagnetic magnetostatic coupling mechanism practically unsuitable for application in GMR devices.

### SUMMARY OF THE INVENTION

An aim of the present invention is to disclose a magnetic system having a basic GMR-stack and further including means for influencing at least one intrinsic magnetic characteristic of the basic GMR-stack of the system. It is another aim of the present invention to disclose a magnetic system being based on the GMR-effect, and further including means for influencing at least one intrinsic magnetic characteristic of the basic GMR-stack of the system, wherein at least part of the magnetic system is manufacturable without significantly changing a standard production process to thereby make systems at a reasonable cost. It is a further aim of the present invention to disclose a magnetic system being based on the GMR- or TMR effect, at least part of the system being made in a multilayer configuration that includes means for influencing at least one intrinsic magnetic characteristic of the basic GMR- or TMR-stack of the system, and the means for influencing the intrinsic magnetic characteristic being made without introducing extra magnetic components outside of the multilayer configuration.

Several aspects of the invention are summarized herebelow. The different aspects and embodiments of the invention that are explained in this section and throughout the whole specification can be combined. A number of terms that is used in this summary and throughout the specification is explained at the end of this section.

In a first aspect of the present invention a data storage system comprising a set of structures is disclosed. The data storage system includes a first structure of layers including at least a first ferromagnetic layer and a second ferromagnetic layer with at least a separation layer of a non-magnetic material therebetween, said first structure having at least a magneto resistance effect. The non-magnetic material of the separation layer is a metal. The data storage system further comprises a second structure including at least one magnetic layer, said second structure influencing at least one intrinsic magnetic characteristic of said first structure; and said second structure being separated from said first structure by at least a spacer layer of a high-resistive metallic and said spacer layer furthermore causing a mainly ferromagnetic coupling of said second structure on said first structure while not substantially influencing the magnitude of the magneto resistance effect of said first structure.

In a GMR stack, with a current-in-plane configuration, the high-resistive metallic material is chosen i.a. in order to avoid that the magnitude of the magneto resistance effect is reduced significantly due to electrical shunting. The desired ferromagnetic coupling is obtained by exploiting the ferromagnetic coupling due to the waviness or roughness of the magnetic layers (often called “orange-peel coupling” or topological coupling). Correlated waviness of magnetic layers which are separated by the high-resistive metallic material of the non-magnetic spacer layer causes a ferromagnetic coupling, because in the case of parallel magnetizations the magnetic flux will cross the non-magnetic spacer layer from one magnetic layer to the other, and this makes the situation with parallel magnetizations energetically favorable over an antiparallel configuration. Ferromagnetic coupling mechanisms which are caused by interactions on a microscopic scale are therefore independent of the geometry of the magnetoresistive device and are homogeneous over the area of the magnetoresistive device.

The set of structures of the data storage system of the invention can be made in a multilayer configuration building further on the basic GMR-stack of the system. Therefore at least part of the system is manufacturable without significantly changing a standard production process to thereby make at least part of the system at a low cost. There can be several intermediate layers in-between said first structure and said spacer layer of a high-resistive metallic material, and in-between said spacer layer of a high-resistive metallic material and said second structure. The set of structures can be made without the need for introducing extra magnetic components outside of the multilayer configuration. It is possible in an embodiment of the invention to integrate the whole data storage system on one semiconductor (silicon) chip with the multilayer configuration being grown or deposited on the chip. The multilayer configuration can be grown or deposited on the chip in the front-end or in the back-end of the process for making the chip. In the back-end process a part of the chip is planarized and the multilayer configuration is deposited or grown thereon. Appropriate connections by bonding or via structures are made in order to transfer the signals of the multilayer configuration to the part of the chip containing the signal processing logic. In the front-end process, the multilayer configuration is directly integrated on the semiconductor (silicon).

In an advantageous embodiment of the invention, said spacer layer of a high-resistive metallic material furthermore is at least partially inducing a crystallographic characteristic on said second structure. The spacer layer of a high-resistive metallic material can also induce a crystallographic characteristic on said first structure in case the first structure is above the layer of a high-resistive metallic material. In this way, depending on the choice of crystallographic characteristic of the high-resistive metallic material, the preferred or needed crystallographic structure of the second or first structure (depending which of the second or first structure is above the layer of a high-resistive metallic material) can be selected. The crystallographic characteristic can, for the same high-resistive metallic material, include a different orientation of the high-resistive metallic material, for example (111) or (100) or (110), or another phase structure of the high-resistive metallic material. There are further implementations of this embodiment of the invention. The second structure can be deposited on the spacer layer of a high-resistive metallic material or said spacer layer can de deposited on the second structure. In both implementations, the crystallographic structure of the spacer layer of a high-resistive metallic material can be induced or transferred to the second structure.

In order to compensate for example for the intrinsic magnetic characteristic of field offset of the magneto resistance output curve of the basic GMR-stack of the system of the invention, in an embodiment of the invention the second structure can comprise at least one layer of a magnetic material of a high coercivity. Said second structure can also comprise at least one layer of an exchange biasing or an exchange biased magnetic material or a layer that has a magnetization direction that has a preferential orientation with respect to the magnetization direction of said first ferromagnetic layer. Preferably the layer that has a preferential orientation is oriented substantially anti-parallel with respect to the magnetization direction of said first ferromagnetic layer. The second structure can also be a layer with an orientation of the magnetization of the layer under an angle between 90° and 180° with respect to the magnetization direction of said first ferromagnetic layer to eliminate both field-offset and hysteresis of said first structure at the same time. The orientation of the magnetization direction of the second structure can also be influenced by the crystallographic structure induced by the crystallographic characteristic of the high-resistive metallic material.

The data storage system of the invention can further comprise a third structure including at least one magnetic layer, said third structure influencing at least one magnetic characteristic of said first structure, said second structure at least partly compensating for the influencing of said third structure on said first structure. This embodiment is advantageous in case for instance the magnetization pinning of the first ferromagnetic layer of said first structure, is strengthened through the addition of said third structure to the data storage system. Another type of said third structure can be the presence of a third layered structure for reducing the coercivity of the second ferromagnetic layer of the first structure. This third structure can also be separated from the first structure by a layer or a stack of layers including at least a layer of a high-resistive metallic material and said layer of a high-resistive metallic material furthermore causing a mainly ferromagnetic coupling of said third structure on said first structure while not substantially influencing the magnitude of the magneto resistance effect of said first structure.

The system of the invention can have as the spacer layer of a high-resistive metallic material, a layer composed of a material of one of the group of Ti, Zr, Hf, V, Nb, and Ta, or any combination thereof. The spacer layer may also be composed of a material of one of the group of Mo, Cr, W, or any combination thereof, or may be a polymer or any other metallic material with a resistivity in the range of the typical resistivities of the group of the metals Ti, Zr, Hf, V, Nb, Ta, Mo, Cr, and W or any combination thereof. It is one of the advantages of the present invention that the influencing of the coupling of said second structure on said first structure through said spacer layer of a high-resistive metallic material is not strongly sensitive to small variations in the thickness of the spacer layer of high-resistive metallic material. Nevertheless the degree of influencing of the intrinsic magnetic characteristic of said first structure can depend on the thickness of the layer of high-resistive metallic material and therefore the intrinsic magnetic characteristic of said first structure can also be tuned by varying the thickness of the layer of high-resistive metallic material.

Thus the strength of the coupling is not critically dependent on the precise thickness of the layer of high-resistive metallic material but the influencing of the intrinsic magnetic characteristic of said first structure can depend on the thickness of the spacer layer of high-resistive metallic material. The thickness of the spacer layer can be as thin as one atomic layer or can have a thickness of up to 2 or 3 or 5 or 7 or 10 or even 15 nm. Preferably a Ta layer with a thickness of about 3 nm is used for the spacer layer of a high-resistive metallic material. The layers of the data storage system of the invention can be deposited by Molecular Beam Epitaxy or MOCVD or sputter deposition or any such deposition technique known to the person of skill in the art.

The data storage system of the invention can be a magnetic memory element or a magnetic memory device and can also be a computer or an integrated circuit with a memory functionality such as a MRAM or an ASIC with an embedded non-volatile magnetic memory element or a chipcard or any such data storage system. The set of structures of the data storage system of the invention can be made in a multilayer configuration building further on the basic GMR-stack of the system. As such but also in other configurations, the set of structures can be part of a MRAM structure being integrated on a semiconductor substrate. The set of structures can also be part of a non-volatile magnetic memory structure being integrated on a semiconductor substrate. The MRAM data storage systems can be based on GMR spin valves, replacing CMOS capacitors and embedded in a conventional semiconductor chip environment. A typical MRAM cell unit consists of layers of magnetic material separated by a thin non-magnetic metal in which electrons flow (a basic GMR-stack). The magnetic orientation in the magnetic layers can be independently controlled by applying a magnetic field. The field is created by passing pulses of electric current through thin wires next to, or incorporated in, the MRAM cells. When the magnetizations of the magnetic layers have the same orientation, the resistance is low because the spin dependent scattering of the transported electrons is relatively low. The cell can therefore be switched between two states, representing a binary 0 and 1.

For magnetic storage the orientation of one of the magnetic layers can be kept fixed and pinned by an antiferromagnet. Because data in an MRAM is stored magnetically, the data is kept whether the device is powered or not, i.e., it is non-volatile. Advantages of the MRAM include: higher speed than today's static RAM and higher density than DRAM because the signal height does not scale with the cell area of the magnetic element. The read/write times can be as short as 10 nanoseconds, about six times faster than today's fastest RAM memory. Furthermore, the relatively simple principle permits more flexibility in circuit design.

In a second aspect of the present invention, a sensing system of a magnetic characteristic is disclosed. The sensing system comprises a first structure of layers including at least a first ferromagnetic layer and a second ferromagnetic layer with at least a separation layer of a non-magnetic material therebetween, said first structure having at least a magneto resistance effect. The non-magnetic material of the separation layer is a metal. The sensing system further comprises a second structure and said second structure being separated from said first structure by at least a spacer layer of a high-resistive metallic and said spacer layer furthermore causing a mainly ferromagnetic coupling of said second structure on said first structure while not substantially influencing the magnitude of the magneto resistance effect of said first structure. In a GMR stack, with a current-in-plane configuration, the high-resistive metallic material is chosen i.a. in order to avoid that the magnitude of the magneto resistance effect is reduced significantly due to electrical shunting. The desired ferromagnetic coupling is obtained by exploiting the ferromagnetic coupling due to the waviness or roughness of the magnetic layers (often called “orange-peel coupling” or topological coupling). Correlated waviness of magnetic layers which are separated by the high-resistive metallic material of the non-magnetic spacer layer causes a ferromagnetic coupling, because in the case of parallel magnetizations the magnetic flux will cross the non-magnetic spacer layer from one magnetic layer to the other, and this makes the situation with parallel magnetizations energetically favorable over an antiparallel configuration. Ferromagnetic coupling mechanisms which are caused by interactions on a microscopic scale are therefore independent of the geometry of the magnetoresistive device and are homogeneous over the area of the magnetoresistive device.

The sensing system according to the second aspect of the invention can be a magnetic sensor device or a magnetic read-head such as a GMR thin film head for hard disks or any such system including signal processing electronics for processing the signal of the magnetic characteristic or a measure or derivate thereof. The set of structures of the sensing system of the invention can be made in a multilayer configuration building further on the basic GMR-stack of the system. Therefore at least part of the system is manufacturable without significantly changing a standard production process to thereby make at least part of the system at a low cost. There can be several intermediate layers in-between said first structure and said spacer layer of a high-resistive metallic material, and in-between said spacer layer of a high-resistive metallic material and said second structure. The set of structures can be made without the need for introducing extra magnetic components outside of the multilayer configuration. It is possible in an embodiment of the invention to integrate the whole sensing system on an Alsimag (a mixture of oxides) slider or on one semiconductor (silicon) chip with the multilayer configuration being grown or deposited on the chip. The multilayer configuration can be grown or deposited on the chip in the front-end or in the back-end of the process for making the chip. In the back-end process a part of the chip is planarized and the multilayer configuration is deposited or grown thereon. Appropriate connections by bonding or via structures are made in order to transfer the signals of the multilayer configuration to the part of the chip containing the signal processing logic. In the front-end process, the multilayer configuration is directly integrated on the semiconductor (silicon). The sensing system of the invention can also be an integrated circuit with a memory functionality and an integrated sensing system or an ASIC with an embedded non-volatile magnetic memory element and a sensing system or a chipcard with a sensing system or any such sensing system. The set of structures of the sensing system of the invention can be made in a multilayer configuration building further on the basic GMR-stack of the system.

In an advantageous embodiment of the invention, in which the second structure is on top of the high-resistive metallic material, said spacer layer of a high-resistive metallic material furthermore is at least partially inducing a crystallographic characteristic on said second structure. In this way, the preferred or needed crystallographic structure of the second structure can be selected. There are at least two implementations of this embodiment of the invention. The second structure can be deposited on the spacer layer of a high-resistive metallic material or said layer can de deposited on the second structure. In both implementations, the crystallographic structure of the layer of a high-resistive metallic material can be induced or transferred to the second structure.

In order to compensate for example for the intrinsic magnetic characteristic of field offset of the magneto resistance output curve of the basic GMR-stack of the system of the invention, in an embodiment of the invention the second structure can comprise at least one layer of a magnetic material of a high coercivity. Said second structure can also comprise at least one layer of an exchange biased magnetic material or a layer that has a magnetization direction that has a preferential orientation with respect to the magnetization direction of said first ferromagnetic layer. Preferably the layer that has a preferential orientation is oriented substantially anti-parallel with respect to the magnetization direction of said first ferromagnetic layer. The second structure can also be a layer with an orientation of the magnetization of the layer under an angle between 90° and 180° with respect to the magnetization direction of said first ferromagnetic layer to eliminate both field-offset and hysteresis of said first structure at the same time.

The sensing system of the invention can further comprise a third structure including at least one magnetic layer, said third structure influencing at least one magnetic characteristic of said first structure, said second structure at least partly compensating for the influencing of said third structure on said first structure. This embodiment is advantageous in case for instance the magnetization pinning of the first ferromagnetic layer of said first structure, is strengthened through the addition of said third structure to the sensing system. Another type of said third structure can be the presence of a third layered structure for reducing the coercivity of the second ferromagnetic layer of the first structure. This third structure can also be separated from the first structure by a layer or a stack of layers including at least a spacer layer of a high-resistive metallic material and said spacer layer of a high-resistive metallic material furthermore causing a mainly ferromagnetic coupling of said third structure on said first structure while not substantially influencing the magnitude of the magneto resistance effect of said first structure.

The system of the invention can have as the spacer layer of a high-resistive metallic material, a layer composed of a material of one of the group of Ti, Zr, Hf, V, Nb, and Ta or any combination thereof. The spacer layer may also be composed of a material of one of the group of Mo, Cr, and W or any combination thereof, or may be a polymer or any other metallic material with a resistivity in the range of the typical resistivities of the group of the metals Ti, Zr, Hf, V, Nb, Ta, Mo, Cr, W or any combination thereof. It is one of the advantages of the present invention that the mainly ferromagnetic coupling of said second structure on said first structure through said spacer layer of a high-resistive metallic material is not strongly sensitive to small variations in the thickness of the layer of high-resistive metallic material. The thickness of the spacer layer can be as thin as one atomic layer or can have a thickness of up to 2 or 3 or 5 or 7 or 10 or even 15 nm. Preferably a Ta layer with a thickness of about 3 nm is used for the spacer layer of a high-resistive metallic material. The layers of the sensing system of the invention can be deposited by Molecular Beam Epitaxy or MOCVD or sputter deposition or any such deposition technique known to the person of skill in the art.

In a third aspect of the present invention, a method of fabricating a magnetic system is disclosed. The magnetic system can be a data storage system or a sensing system. The method comprises the steps of defining a first structure of layers including at least a first ferromagnetic layer and a second ferromagnetic layer with at least a separation layer of a non-magnetic metallic material therebetween, said first structure having at least a magneto resistance effect; defining a second structure, said second structure including at least one magnetic layer or a set of layers for influencing at least one intrinsic magnetic characteristic of said first structure; and defining at least one layer of a high-resistive metallic material in-between said second structure and said first structure, and said layer of a high-resistive metallic material furthermore at least partially inducing a crystallographic characteristic on said second structure. The layers of the magnetic system of the invention can be deposited by Molecular Beam Epitaxy or MOCVD or sputter deposition or any such deposition technique known to the person of skill in the art.

In a fourth aspect of the present invention, a method of tuning an intrinsic magnetic characteristic of a magnetic system is disclosed, the system comprising a set of structures including a first structure of layers including at least a first ferromagnetic layer and a second ferromagnetic layer with at least a separation layer of a non-magnetic metallic material therebetween, said first structure having at least said magneto resistance effect. The magnetic system can be a data storage system or a sensing system. The method comprises the steps of defining a layer of a high-resistive metallic material on said first structure; and defining a second structure including at least one magnetic layer on said layer of said high-resistive metallic material, said second structure including at least one magnetic layer or a set of layers for influencing at least one intrinsic magnetic characteristic of said first structure. There can be several intermediate layers in-between said first structure and said layer of a high-resistive metallic material, and in-between said layer of a high-resistive metallic material and said second structure.

In a fifth aspect of the present invention a magnetic system such as data storage system or a sensing system of a magnetic characteristic is disclosed. The system comprises a set of structures including:

a first structure of layers including at least a first ferromagnetic layer structure and a second ferromagnetic layer with at least a separation layer of a non-magnetic material therebetween, said first structure having at least a magneto resistance effect;

a second structure including at least one magnetic layer, said second structure influencing at least one intrinsic magnetic characteristic of said first structure;

said second structure being separated from said first structure by at least a layer of a high-resistive metallic material and said layer of a high-resistive metallic material furthermore influencing the coupling of said second structure on said first structure while not substantially influencing the magnitude of the magneto resistance effect of said first structure; and wherein

said first ferromagnetic layer structure and said second structure respectively comprise an even or odd number of non-abutting ferromagnetic layers and an odd or even number of non-abutting ferromagnetic layers. Thus, according to this fifth aspect of the invention, in case the first ferromagnetic layer structure comprises an even number of non-abutting ferromagnetic layers, the second structure comprises an odd number of non-abutting ferromagnetic layers, and vice-versa. In this special situation the magnetisation directions of the exchange biasing material in the first structure of layers and in the second structure have the same direction. The exchange biasing material, like IrMn, preferably has a high blocking temperature and guarantees a good temperature stability. The magnetisation directions of the exchange biasing material can be very well oriented by heating the stack of layers above the blocking temperature in an applied magnetic field. Therefore, by changing the orientation of the magnetisation directions of the exchange biasing material in the first structure of layers and in the second structure, the complete multilayer configuration can be (re-)oriented by field-cooling after deposition. Generally this is possible for any combination of even with odd numbers of ferromagnetic layers.

The layers of the system can be deposited by Molecular Beam Epitaxy or MOCVD or sputter deposition or any such deposition technique known to the person of skill in the art.

With reference to the claims, it is noted that various characteristic features as defined in the set of claims may occur in combination. Moreover, it is to be noted that the expression layer structure wherever used in this document may imply a single layer or a stack of layers.

A number of terms that is used in this summary and throughout the specification is explained herebelow. With the term intrinsic magnetic characteristic, it is meant any magnetic characteristic of the GMR- or TMR-structure that is intrinsically related to the magneto resistance effect of the GMR- or TMR-structure. Such include the presence of field-offset and hysteresis of the GMR- or TMR-structure but not the stray field of the GMR- or TMR-structures as the stray field is not directly related to the magneto resistance characteristic of the structure, device or system. Thus the term intrinsic magnetic characteristic may, in the light of the above explanation, be renamed as an intrinsic magneto resistance characteristic. The term high-resistive metallic material is to be understood according to the knowledge of the person skilled in the art. Cu or Al obviously are low-resistive metallic materials. The resistivity of the metallic material is to be sufficiently high for not substantially influencing the magnitude of the magneto resistance effect of said first structure. A high-resistive metallic material for example is a material with a resistivity in about the range of the typical resistivities of the group of the metals Ti, Zr, Hf, V, Nb, Ta, Mo, Cr, and W or any combination thereof.

FIG. 1 shows schematically part of a system of the invention according to an embodiment as a multilayer configuration.

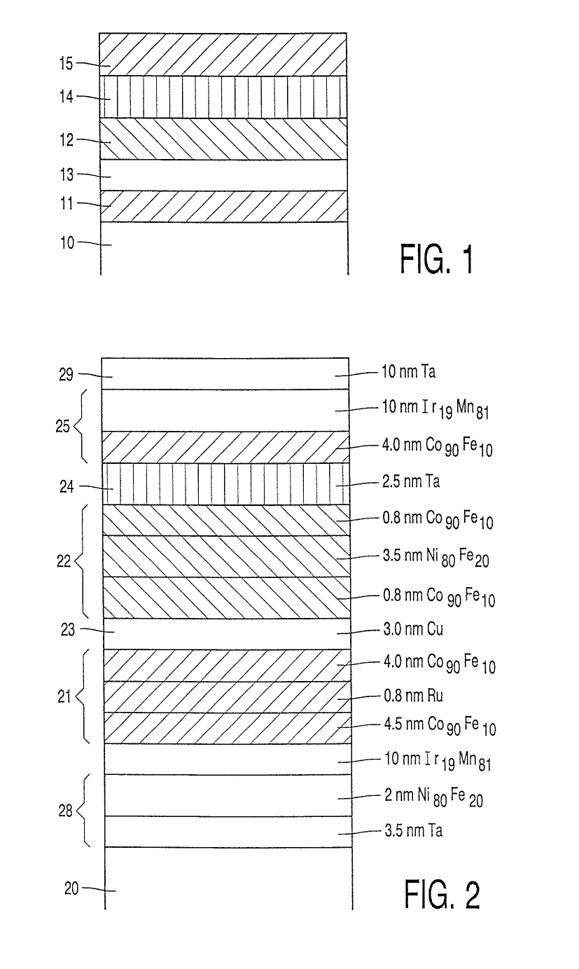

FIG. 2 shows part of a system of the invention according to an embodiment as a multilayer configuration with an exchange-biased artificial antiferromagnet.

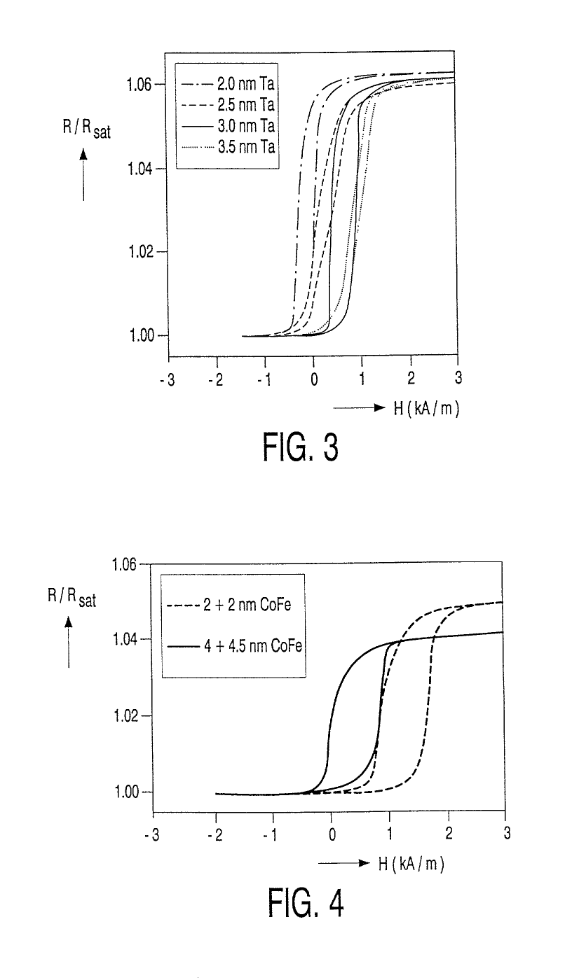

FIG. 3 shows how the field offset of a GMR-structure as part of a system of the invention can be tuned by varying the thickness of a Ta layer. The Ta layer is separating the GMR-structure from a second structure including a 4.0 CoFe/10.0 IrMn/10.0 Ta (all numbers in nm) layer stack.

FIG. 4 shows data of the offset compensation of layer structures with an AAF according to an embodiment of the invention as a multilayer configuration.

For the purpose of teaching of the invention, preferred embodiments of the method and of devices of the invention are described in the sequel. In particular embodiments of the invention of magnetic multilayer configurations based on a basic GMR-stack are disclosed. These multilayer configurations can be integrated in the systems of the invention according to techniques known to the person of skill in the art. It is for example possible in an embodiment of the invention to integrate the whole sensing or data storage system on one semiconductor (silicon) chip with the multilayer configuration being grown or deposited on the chip. The multilayer configuration can be grown or deposited on the chip in the front-end or in the back-end of the process for making the chip. In the back-end process a part of the chip is planarized and the multilayer configuration is deposited or grown thereon. Appropriate connections by bonding or via structures are made in order to transfer the signals of the multilayer configuration to the part of the chip containing the signal processing logic. It will be apparent to the person skilled in the art that other alternative and equivalent embodiments of the invention can be conceived and reduced to practice without departing form the true spirit of the invention, the scope of the invention being limited only by the appended claims.

In the sequel magnetic systems are disclosed that comprise a set of structures. The set of structures comprises a first structure of layers including at least a first ferromagnetic layer and a second ferromagnetic layer with at least a separation layer of a non-magnetic material therebetween, said first structure having at least a magneto resistance effect. The non-magnetic material of the separation layer is a metal. The set of structures system further comprises a second structure including at least one magnetic layer, said second structure influencing at least one intrinsic magnetic characteristic of said first structure; and said second structure being separated from said first structure by at least a spacer layer of a high-resistive metallic material and said spacer layer furthermore causing a mainly ferromagnetic coupling of said second structure on said first structure while not substantially influencing the magnitude of the magneto resistance effect of said first structure.

FIG. 1 shows schematically a first embodiment of a multilayer configuration as part of the system of the invention. Shown in the FIG. is a substrate (10) whereon is deposited a first ferromagnetic layer (11) and a second ferromagnetic layer (12) with a separation layer (13) of a non-magnetic material therebetween. This first structure is a spin valve multilayer with a magneto resistance effect and contains a pinned magnetic layer (11) and a free magnetic layer (12). A second structure comprising a pinned layer (15) is separated from this first structure by a spacer layer of a high-resistive metallic material (14) is deposited thereon. A thin Ta layer is used as the high-resistive metallic material (14). The Ta layer is causing a mainly ferromagnetic coupling of said second structure on said first structure, said second structure influencing at least one intrinsic magnetic characteristic of said first structure, while not substantially influencing the magnitude of the magnetoresistance effect of said first structure.

The second ferromagnetic layer of the first structure of layers, which is the free magnetic layer, experiences weak coupling fields such as magnetostatic antiferromagnetic coupling and ferromagnetic “orange-peel” coupling. By incorporating a dominant mainly ferromagnetic coupling from a pinned magnetic layer (15) in the second structure which allows the magnetization of the pinned magnetic layer to be anti-parallel to the magnetization of the first pinned layer, the coupling effects are neutralized.

In this embodiment, it is not the goal to implement a “mirror” of both the exchange- and magnetostatic coupling over the separation layer, but merely to compensate the field offset of the basic GMR-stack by an opposite (basically “orange-peel”) ferromagnetic coupling field over the Ta layer. Experimentally it is found that

the strength of the coupling is not very sensitive to small variations in the Ta layer thickness;

varying the Ta layer thickness on the other hand has an influence on the field offset of the basic GMR-stack (see below);

Ta has a relative high resistivity and therefore doesn't reduce the MR effect too much in the basic GMR-stack;

Ta induces/transfers the desired (111) texture for this application to the upper layer (15); the GMR effect over Ta is very small, so that it doesn't cancel the GMR effect of the basic GMR-stack.

An embodiment with an extra advantage is obtained if an exchange-biased artificial antiferromagnet (AAF) is used in the active part of the basic GMR-stack, while a single ferro-magnetic layer is used in the offset-compensating subsystem (see FIG. 2). In this configuration the exchange-biasing directions are the same, and therefore the complete multilayer configuration can still be (re-)oriented by field-cooling after deposition. Generally this is possible for any combination of even with odd numbers of ferromagnetic layers.

FIG. 2 shows the embodiment with an exchange-biased artificial antiferromagnet. An artificial antiferromagnet is a layer structure comprising alternating ferromagnetic and non-magnetic layers which have through the choice of materials and layer thicknesses such an exchange coupling that the magnetization directions of the ferromagnetic layers are antiparallel in the absence of an external magnetic field. Each ferromagnetic layer can comprise another set of ferromagnetic layers. According to the embodiment of FIG. 2, on a substrate (20) is provided a multilayer configuration of subsequently

a buffer layer (28) to induce the right material structure, (111) texture, in this case the buffer layer is a stack of 3.5 nm Ta/2.0 nm Ni₈₀Fe₂₀;

a first structure (21-3) containing:

a layer structure consisting of an exchange-biased AAF, in this case 10.0 nm Ir₁₉Mn₈₁/4.5 nm Co₉₀Fe₁₀/0.8 nm Ru/4.0 nm Co₉₀Fe₁₀; the CoFe/Ru/CoFe stack is used as the first ferromagnetic layer (21) (the pinned layer); Ir₁₉Mn₈₁ (the exchange biasing layer) has been chosen as the exchange biasing material because of its high blocking temperature (around 560 K) for a good temperature stability; the use of an AAF as pinned layer provides an excellent magnetic stability because of its very small nett magnetization, resulting in a great rigidity;

a separation layer (23) of 30 nm Cu;

a free layer (the second ferromagnetic layer, (22)) of 0.8 nm Co₉₀Fe₁₀/3.5 nm Ni₈₀Fe₂₀/0.8 nm Co₉₀Fe₁₀ (the thin Co₉₀Fe₁₀ layers enhance the GMR ratio and limit interlayer diffusion, thereby improving the thermal stability);

and the multilayer configuration further comprising:

a high-resistive metallic layer (24) of 2.5 nm Ta

a second structure (25) comprising

a second pinned layer (25) consisting of 4.0 nm Co₉₀Fe₁₀ exchange-biased with 10.0 nm Ir₁₉Mn₈₁; and finally

a cap layer (29) of 10.0 nm Ta for protection.

One can note that the magnetization directions of the two ferromagnetic layers closest to the free ferromagnetic layer are oriented oppositely. In this way a cancellation of the coupling fields and therefore the elimination of the field-offset in the magneto resistance characteristic can be achieved with a correct choice of the Ta layer thickness. The GMR effect, however, is not cancelled because the high-resistive Ta coupling layer provides almost no GMR effect in the upper part of the multilayer.

An extension of this embodiment is to choose the magnetization of the additional layer under an angle between 90° and 180° to eliminate both field-offset and hysteresis at the same time.

In principle also another metal than Ta could be used in the above embodiments as long as it has a relatively high resistivity, causes no significant GMR effect and does not disturb the texture of the multilayer.

The invention according to these embodiments has a number of advantages:

Exact mirroring of both the exchange- and magnetostatic coupling is not required;

By using a highly resistive material like Ta (which at the same time can induce the desired (111) texture) this idea can also be used in GMR multilayers (see below);

The use of an AAF makes it robust, and therefore also suitable for automotive/industrial sensor applications and for read heads;

By using an odd and an even AAF the completed multilayer can still be reset or reoriented after deposition, for example, to realize crossed anisotropies or to repair the exchange biasing.

In a best mode embodiment of the invention a GMR multilayer configuration consisting of 3.5 Ta/2.0 NiFe/10.0 IrMn/4.5 CoFe/0.8 Ru/4.0 CoFe/3.0 Cu/0.8 CoFe/3.5 NiFe/0.8 CoFe/2.5 Ta/4.0 CoFe/10.0 IrMn/10.0 Ta (all numbers in nm) is disclosed. This configuration is deposited on a silicon wafer substrate. A Ta-layer of 3.5 nm thick is deposited on the substrate and on this Ta layer a stack of layers is deposited. The first structure is the IrMn/CoFe/Ru/CoFe/Cu/CoFe/NiFe/CoFe stack; the second structure is the CoFe/IrMn bilayer structure; the 2.5 nm Ta layer is the spacer layer of high resistive metallic material. FIG. 3 shows that the field offset of the basic GMR-stack can be tuned by varying the thickness of the Ta layer. FIG. 3 shows that the field offset can be tuned to even negative values depending on the thickness of the Ta layer. In a number of applications such tuning to negative field offsets can be advantageous. This embodiment is also an example of the fifth aspect of the invention wherein a magnetic system such as data storage system or a sensing system of a magnetic characteristic is disclosed. This system comprises a set of structures including the first structure of layers and the second structure including at least one magnetic layer, said second structure being separated from said first structure by at least the spacer layer of a high-resistive metallic material. The first ferromagnetic layer structure of the first structure is the 4.5 CoFe/0.8 Ru/4.0 CoFe stack (an even number of non-abutting ferromagnetic layers with the Ru spacer layer) and said second structure is the 4.0 CoFe/10.0 IRMn stack (an odd number (one layer) of non-abutting ferromagnetic layers). The second structure can also be a CoFe/NiFe/IrMn stack wherein the abutting CoFe/NiFe structure is seen as one ferromagnetic layer (non-abutting ferromagnetic layers).

Yet in another embodiment of the present invention, another robust multilayer configuration is disclosed wherein an AAF is used instead of a single ferromagnetic layer as the second structure. Experimental data of such multilayer, consisting of, for example, 3.5 Ta/2.0 NiFe/10.0 IrMn/4.5 CoFe/0.8 Ru/4.0 CoFe/3.0 Cu/0.8 CoFe/5.0 NiFe/2.2 Ta/t₁ CoFe/0.8 Ru/t₂ CoFe/10.0 IrMn/10.0 Ta, (all numbers in nm) are presented in FIG. 4 (t , t₂=2, 2 nm for the characteristic with the ---- line; t₁, t₂=4, 4, 5 nm for the characteristic with the ____ line).

In yet another embodiment of the present invention, a way of applying a longitudinal bias field is disclosed which, apart from altering the multilayer stack, does not require any extra processing steps. A layer structure is first deposited and the field during deposition of these layers is rotated over 90° with respect to that field which is used to deposit the second pinned layer (the second structure). An example structure is

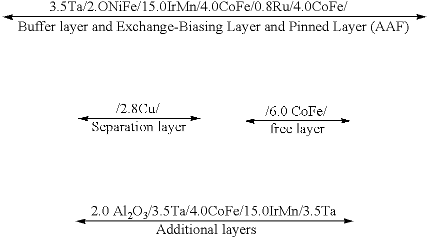

(all numbers in nm) with the layer stack of the additional layers including a high-resistive metallic material (the 3.5 nm Ta layer on the Al₂O₃ layer) and the second pinned layer (the second structure). The Al₂O₃ layer is an intermediate layer in between the first structure of layers and the spacer layer of a high-resistive metallic material.

This embodiment of the invention can be used in future generations of magnetic read heads and MRAM systems. This multilayer stack addresses the problem of the magnetic characteristic coercive field of the free layer of both GMR spin-valves and TMR structures. When the moment of this layer is aligned with the stray field from a passing disk, an anti-parallel alignment with the pinned layer moment may be achieved. This gives rise to a large change in resistance. If a magnetic coercivity exists in the free layer, the magnetization of this layer aligns with the field by introducing domain walls which move through the layer erratically and thereby introduce distortion in the output of the GMR sensor. The stray field from the passing disk is directed to be parallel with a magnetization direction of the first layer structure, i.e. the H-direction during deposition. The longitudinal biasing field is uni-directional and serves the same purpose as the field from biasing permanent magnets or a bias conductor as used in the prior art. Thus, additional layers are used to longitudinally pin a GMR-structure. In doing so the coercivity of the free layer is reduced to zero; this results in less distortion in the output of the GMR-structure.

1. A data storage system comprising a set of structures including:
a first structure of layers including at least a first ferromagnetic layer and a second ferromagnetic layer with at least a separation layer of a non-magnetic material therebetween, said first structure having at least a magneto resistance effect;
a second structure including at least one magnetic layer, said second structure influencing at least one intrinsic magnetic characteristic of said first structure;
and said second structure being separated from said first structure by at least a spacer layer, wherein the non-magnetic material is a metal and the spacer layer comprises a high-resistive metallic material and said spacer layer furthermore causing a mainly ferromagnetic coupling of said second structure on said first structure while not substantially influencing the magnitude of the magneto resistance effect of said first structure.

2. A system as recited in claim 1 wherein said second structure comprises at least one layer of a magnetic material of a high coercivity.

3. A system as recited in claim 1 wherein said second structure comprises at least one layer of an exchange biasing material.

4. A system as recited in claim 1 wherein said second structure comprises a layer that has a magnetization direction that is substantially anti-parallel with respect to the magnetization direction of said first ferromagnetic layer.

5. A system as recited in claim 1 further comprising a third structure including at least one magnetic layer, said third structure influencing at least one magnetic characteristic of said first structure, said second structure at least partly compensating for the influencing of said third structure on said first structure.

6. A system as recited in claim 1 wherein said layer of a high-resistive metallic material furthermore is at least partially inducing a crystallographic characteristic on said second and/or said first structure.

7. A system as recited in claim 6 wherein said layer of a high-resistive metallic material is one of the group of Ti, Zr, Hf, V, Nb, and Ta, or any combination thereof.

8. A system as recited in claim 6 wherein said layer of a high-resistive metallic material has a thickness in the range of one atomic layer up to 15 nm.

9. A system as recited in claim 6 wherein said layer of a high-resistive metallic material is one of the group of Mo, Cr, and W or any combination thereof.

10. A system as recited in claim 6 wherein said layer of a high-resistive metallic material is a metallic polymer with a conductivity in the range of the conductivities of the group of Ti, Zr, Hf, V, Nb, Ta, Mo, Cr, and W or any combination thereof.

11. A system as recited in claim 6 wherein said second structure is separated from said first structure by at least said layer of said high-resistive metallic material and an insulating layer abutting said layer of said high-resistive metallic material.

12. A system as recited in claim 1 wherein the set of structures is part of a magnetic memory structure such as a MRAM structure, preferably being integrated on a semiconductor substrate.

13. A sensing system of a magnetic characteristic, said system comprising:
a first structure of layers including at least a first ferromagnetic layer and a second ferromagnetic layer with at least a separation layer of a non-magnetic material therebetween, said first structure having at least a magneto resistance effect;
a second structure including at least one magnetic layer, said second structure influencing at least one intrinsic magnetic characteristic of said first structure; and said second structure being separated from said first structure by at least a spacer layer, wherein the non-magnetic material is a metal and the spacer layer comprises a high-resistive metallic material and said spacer layer furthermore causing a mainly ferromagnetic coupling of said second structure on said first structure while not substantially influencing the magnitude of the magneto resistance effect of said first structure.

14. A method of fabricating a magnetic system, the method comprising the steps of:
defining a first structure of layers including at least a first ferromagnetic layer and a second ferromagnetic layer with at least a separation layer of a non-magnetic metallic material therebetween, said first structure having at least a magneto resistance effect;
defining a second structure, said second structure including at least one magnetic layer or a set of layers for influencing at least one intrinsic magnetic characteristic of said first structure; and
defining at least one layer of a high-resistive metallic material in-between said second structure and said first structure, and said layer of a high-resistive metallic material furthermore at least partially inducing a crystallographic characteristic on said second structure.

15. A method of tuning a magneto resistance characteristic of a magnetic system, the system comprising a set of structures including a first structure of layers including at least a first ferromagnetic layer and a second ferromagnetic layer with at least a separation layer of a non-magnetic metallic material therebetween, said first structure having at least said magneto resistance characteristic, the method comprising the steps of:
defining a layer of a high-resistive metallic material on said first structure; and
defining a second structure including at least one magnetic layer on said layer of said high-resistive metallic material, said second structure said second structure including at least one magnetic layer or a set of layers for influencing at least one intrinsic magnetic characteristic of said first structure.

16. A magnetic system such as data storage system or a sensing system of a magnetic characteristic, the system comprising a set of structures including:
a first structure of layers including at least a first ferromagnetic layer structure and a second ferromagnetic layer with at least a separation layer of a non-magnetic material therebetween, said first structure having at least a magneto resistance effect;
a second structure including at least one magnetic layer, said second structure influencing at least one intrinsic magnetic characteristic of said first structure;
said second structure being separated from said first structure by at least a spacer layer of a high-resistive metallic material and said spacer layer of a high-resistive metallic material furthermore influencing the coupling of said second structure on said first structure while not substantially influencing the magnitude of the magneto resistance effect of said first structure; and wherein
said first ferromagnetic layer structure and said second structure respectively comprising an even or odd number of non-abutting ferromagnetic layers and an odd or even number of non-abutting ferromagnetic layers.
